(19) United States
(12) Patent Application Publication
(10) Pub. No.: US 2002/0173062 A1
(43) Pub. Date: Nov. 21, 2002

(54) Method for manufacturing GaN-based LED

(76) Inventors: Lung-Chien Chen, Hsin-Chuang City (TW); Wen-How Lan, Tao-Yuan City (TW); Fen-Ren Chien, Yung-Ho City (TW)

Correspondence Address: SUPREME PATENT SERVICES, POST OFFICE BOX 2339, SARATOGA, CA, 95070, US

(21) Appl. No.: 09/861,402

(22) Filed: May 17, 2001

(51) Int. Cl. H01L 21/00

(52) U.S. Cl. 438/30

(57) ABSTRACT

A method for manufacturing GaN-based LED (Gallium-Nitride based Light-Emitting Diode) is provided for remedy of the defect of central notch in the far field beam pattern of a conventional GaN-based LED by relocating a pair of P-and N-electrodes and reforming the shape of an illuminating surface thereof.

### FIELD OF THE INVENTION

This invention relates to a method for manufacturing GaN based LED (Gallium-Nitride based Light-Emitting Diode), more particularly, it relates to a method for manufacturing GaN-based LED, which uses sapphire wafer as substrate.

### BACKGROUND OF THE INVENTION

In a conventional GaN-based LED (Gallium-Nitride based Light-Emitting Diode), a sapphire wafer is usually implemented to serve for a substrate, and on the back thereof, arrangement of an electrode is considered infeasible because of electrical insulation of the wafer. A disclosed U.S. Pat. No. 5,563,422 has proposed a GaN-based LED shown in the cross-sectional view of FIG. 1A. The GaN-based LED in this case belongs to the III-V group compound semiconductor containing a P-electrode (second electrode) and an N-electrode (first electrode), and the structure thereof comprises:

a substrate 11;

a semiconductor stack structure disposed on the substrate 11, comprising an N-GaN based III-V group compound semiconductor layer 12 and a P-GaN based III-V group compound semiconductor layer 13;

an N-electrode (first electrode) 14 for connection with the N-GaN based semiconductor layer 12;

a transparent conductive layer 16 formed on the P-GaN based semiconductor layer 13; and

a P-electrode (second electrode) 15 for connection with the P-GaN based semiconductor layer 13.

wherein the N-electrode and the P-electrode are diagonally disposed in a pair of opposite corners respectively as shown in FIG. 1B.

And, the procedure for manufacturing above said GaN-based LED comprises:

1. Growing an N-GaN based semiconductor layer 12;

2. Growing a P-GaN based semiconductor layer 13 on the N-GaN based semiconductor layer 12;

3. Dry etching the P-GaN based semiconductor layer 13 by ICP-RIE technology to reach the N-GaN based semiconductor layer 12 for forming an N-contact area 17 by the conventional lithography process and the dry etching techniques;

4. Forming a transparent conductive metallic layer 16 on the P-GaN based semiconductor layer 13 by the conventional lithography process and the evaporating techniques;

5. Forming a P-electrode metallic layer 15 (second electrode) on the P-GaN based semiconductor layer 13 and the transparent conductive layer 16 by the conventional lithography process and the evaporating techniques; and

6. Forming an N-electrode (first electrode) metallic layer 14 by the conventional lithography process and the evaporating techniques. The GaN-based LED lightens in shape of “L” because the pair of electrodes is located diagonally in opposite corners respectively as shown in FIG. 1B, in which the P-electrode 15 is opaque, therefore, the far field beam pattern looks notched in its center portion as shown in FIG. 2.

According to an assay titled “Improved Current Spreading in High-power InGaN LEDs” by Ivan Eliashevich and appeared in vol. 6, issue 3 of magazine “Compound Semiconductor” for April, 2000, an annular contact N-electrode 17a shown in FIG. 3 was suggested for improving “current spreading” of a GaN-based LED with diagonally disposed electrodes. However, the improvement measure is found still incapable of solving the problem of notch in center in the far field beam pattern.

### SUMMARY OF THE INVENTION

To improve abovesaid problem of central notch in far field beam pattern, this invention is to provide an illuminating-surface reformed GaN-based LED (Gallium-Nitride based Light-Emitting Diode) with both a relocated P-electrode and an N-electrode.

The method for manufacturing the GaN-based LED of this invention comprises the following steps:

growing an N-GaN layer on the substrate of a sapphire wafer;

growing a P-GaN layer on the N-GaN layer;

etching the wafer surface by using the conventional lithography process and the dry etching techniques to form an N-type contact area with a trapezoid illuminating surface reserved, which reaches the N-GaN layer through the P-GaN layer;

forming a transparent conductive layer with a via hole on the P-GaN layer by using the conventional lithography process and the evaporating techniques;

forming a metallic layer serving for a P-electrode on the P-GaN layer and the transparent conductive layer and to be filled in the via hole by using the conventional lithography process and the evaporating techniques;

forming a metallic layer serving for an N-electrode on the N-contact area by using the conventional lithography process and the evaporating techniques; and

forming a metallic layer serving for a bonding pad on the P-electrode and the N-electrode respectively by using the conventional lithography process and the evaporating techniques.

For more detailed information regarding advantages or features of this invention, at least an example of preferred embodiment will be elucidated below with reference to the annexed drawings.

### BRIEF DESCRIPTION OF THE DRAWINGS

The related drawings in connection with the detailed description of this invention, which is to be made later, are described briefly as follows, in which:

FIG. 1A is a cross-sectional view of a conventional GaN-based LED;

FIG. 1B is a top view showing a pair of diagonally disposed conventional electrodes;

FIG. 2 is a plotted diagram showing the far field beam pattern of the GaN-based LED shown in FIGS. 1A and 1B;

FIG. 3 is a top view showing an annular contact layer possessed conventional GaN-based LED;

FIG. 4A is a schematic view showing the method of this invention for manufacturing the GaN-based LED;

FIG. 4B is a top view showing a trapezoid illuminating surface possessed GaN-based LED of this invention;

FIG. 5 is a plotted diagram showing a far field beam pattern of the GaN-based LED shown in FIGS. 4A and 4B;

FIG. 6 shows a trapezoid illuminating surface of a GaN-based LED of this invention with two triangular bonding pads located symmetrically with respect to both X and Y axes; and

FIG. 7 is a plotted diagram showing a far field beam pattern of the GaN-based LED shown in FIG. 6.

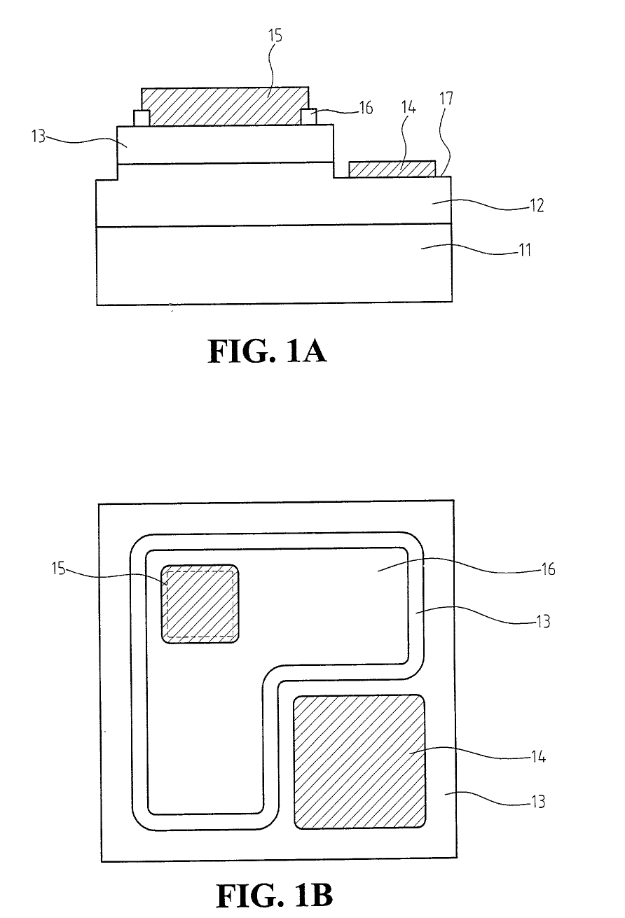

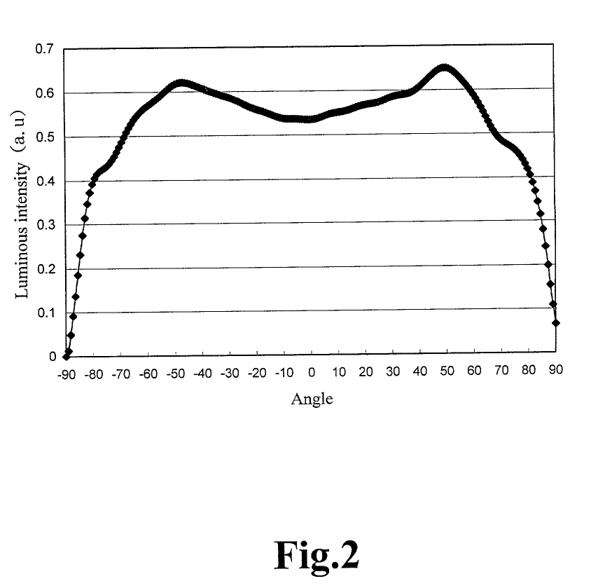

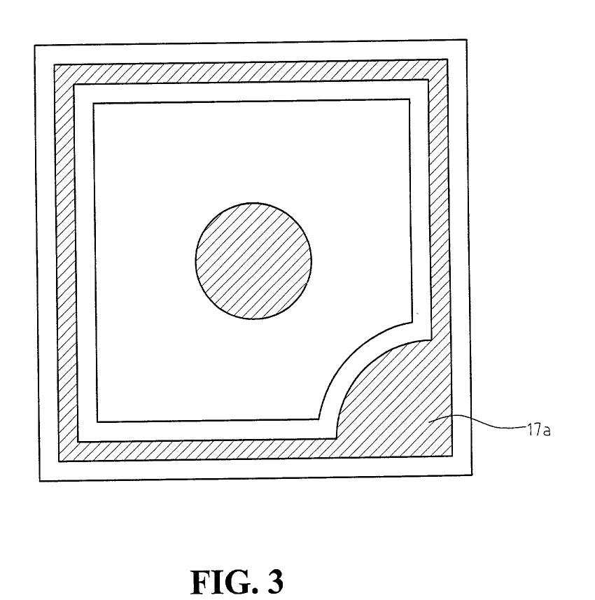

### DETAILED DESCRIPTION OF THE INVENTION

For improving the defect of central notch in far field beam pattern as mentioned, the geometrical shape of the illuminating surface of a GaN-based LED (Gallium-Nitride based Light-Emitting Diode) of this invention is designed in a trapezoid.

The method for manufacturing the GaN-based LED of this invention comprises the following steps:

1. A step for growing an N-GaN layer 42 in a thickness of 2˜3 μm approximately on a substrate of sapphire wafer 41;

2. A step for growing a P-GaN layer 43 in a thickness of 0.1˜1 μm approximately on the N-GaN layer 42;

3. A step for forming a trapezoid mask layer 43a of 200˜10000 Å in thickness made of nickel (Ni), SiO₂ or the like on the P-GaN layer 43, wherein the step further includes several sub-steps as of: coating a photo-resist layer on the mask layer 43a; forming a trapezoid protective layer by using the lithography techniques; removing the part of the mask layer where the photo-resist material is not applied; and removing the photo-resist layer to have the trapezoid mask layer 43a emerged;

4. A step for etching to remove the part of P-GaN layer exposed that means to etch and remove the wafer surface covered by the N-GaN layer 42 and the P-GaN layer 43 by using the ICP-RIE dry etching techniques to form an N-contact area 47 through the P-GaN layer 43 to reach the N-GaN layer 42, where the typical etching depth is about 2000˜14000 Å;

5. A step for removing the trapezoid mask layer 43a;

6. A step for forming a first metallic layer 46 with a via hole 46a on the P-GaN layer 43 for serving as a transparent conductive electrode by using the lithography process and the evaporating techniques, which the first metallic layer 46 is substantially an NiCr film in a thickness of 20˜300 Å;

7. A step for forming a second metallic layer 45 on the P-GaN layer 43 and the transparent conductive electrode 46 by using the lithography process and the evaporating techniques for being filled in the via hole 46a to serve as a P-electrode of NiCr/Au, wherein the typical thickness of NiCr and Au are 50˜2000 Å and 200˜2000 Å respectively;

8. A step for forming a third metallic layer 44 on the N-contact area 47 by using the lithography process and the evaporating techniques for serving as a Ti/Pt/Au N-electrode, wherein the typical thickness of titanium (Ti), platinum (Pt), and gold (Au) are 50˜1000 Å, 50˜1000 Å, and 200˜2000 Å respectively; and

9. A step for forming a second bonding pad 48a containing a Ti/Au metallic layer on the second metallic layer 45 of the P-electrode and a third bonding pad 48b containing a Ti/Au metallic layer on the third metallic layer 44 of the N-electrode, wherein the typical thickness of titanium (Ti) is 50˜10000 Å while that of gold (Au) is 200˜20000 Å of both the second and the third bonding pads 48a, 48b.

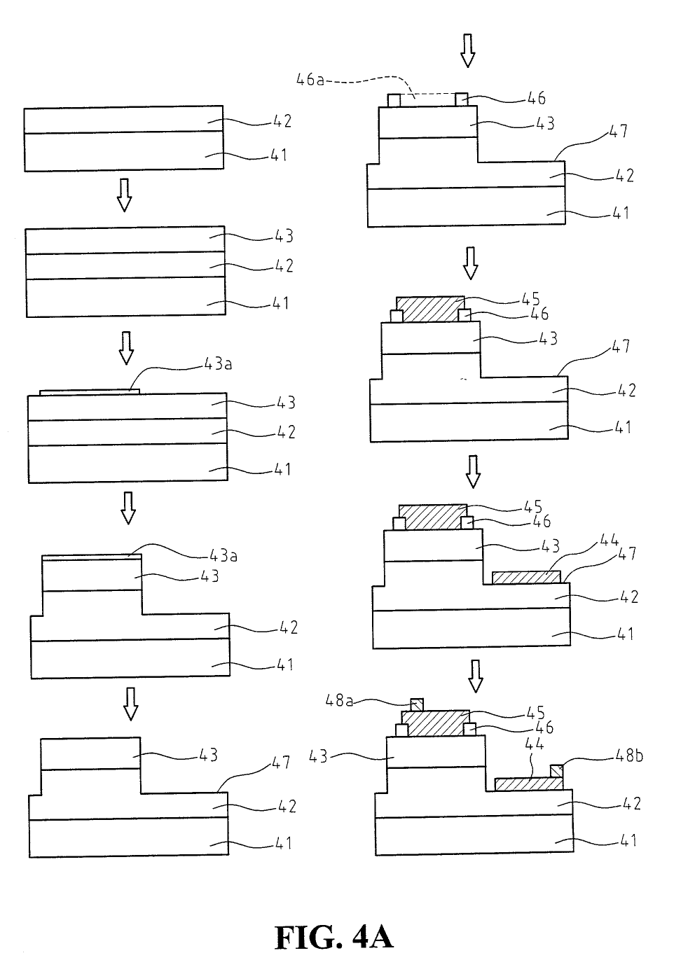

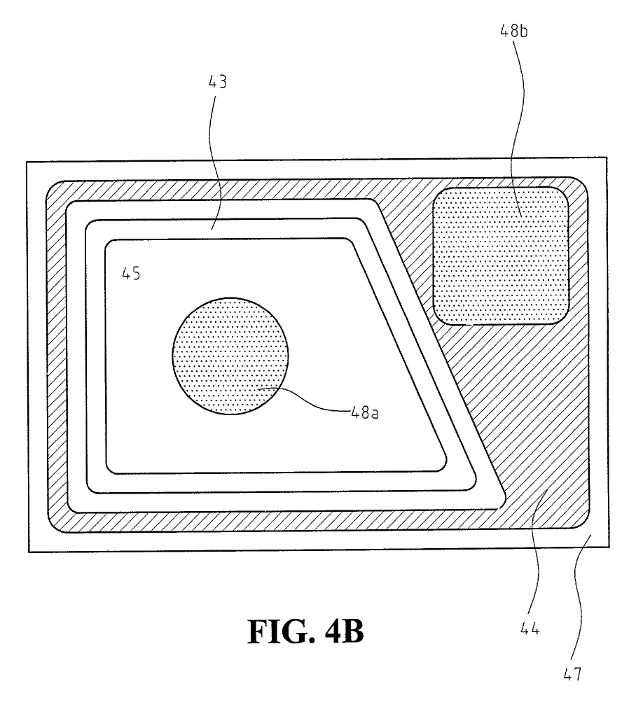

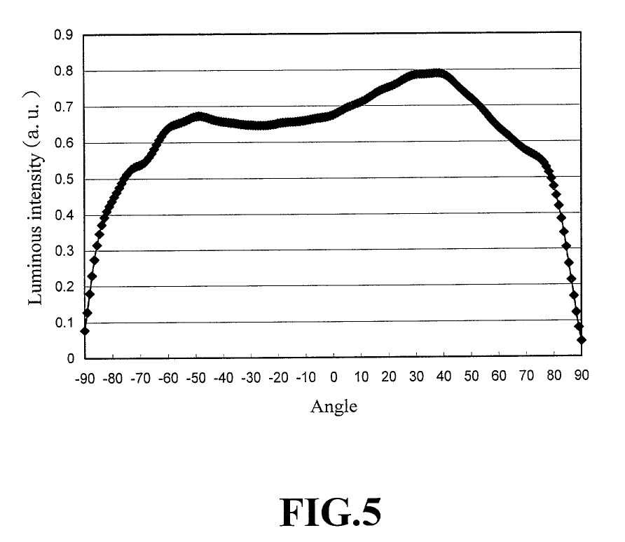

According to a top view of an embodiment of GaN LED of this invention shown in FIG. 4B, a far field beam pattern of the GaN LED made by the method of this invention shown in FIG. 5 is obviously improved in its central notch compared with the conventional one.

In another embodiment of this invention, the geometrical shape of the illuminating surface of a GaN-based LED of this invention is also designed in a trapezoid with two triangular bonding pads located symmetrically with respect to both X and Y axes. An arrangement like this is found capable of solving abovesaid problem regarding the central notch of the far field beam pattern, and additionally, applicable in the flip-chip techniques. The method for manufacturing a GaN-based LED in this embodiment is about the same with the previous one as shown in FIG. 4A except a pair of second and third triangular bonding pads located symmetrically with respect to both X and Y axes.

The other method for manufacturing a GaN-based LED comprises the following steps:

1. A step for growing an N-GaN layer 42 in a thickness of 2˜3 μm approximately on a substrate of sapphire wafer 41;

2. A step for growing a P-GaN layer 46 in a thickness of 0.1˜1 μm approximately on the N-GaN layer 42;

3. A step for forming a trapezoid mask layer 43a of 200˜10000 Å in thickness made of nickel (Ni), SiO₂ or the like on the P-GaN layer 43, wherein the step further includes several sub-steps as of: coating a photo-resist layer on the mask layer 43a; forming a trapezoid protective layer by using the lithography techniques; removing the part of the mask layer where the photo-resist material is not applied; and removing the photo-resist layer to have the trapezoid mask layer 43a emerged;

4. A step for etching to remove the part of P-GaN layer exposed that means to etch and remove the wafer surface covered by the N-GaN layer and the P-GaN layer by using the ICP-RIE dry etching techniques to form an N-contact area 47 through the P-GaN layer 43 to reach the N-GaN layer 42, where the typical etching depth is about 2000˜14000 Å;

5. A step for removing the trapezoid mask layer 43a;

6. A step for forming a first metallic layer 46 with a via hole 46a on the P-GaN layer 43 for serving as a transparent conductive electrode by using the lithography process and the evaporating techniques, which the first metallic layer 46 is substantially an NiCr film in a thickness of 20˜300 Å;

7. A step for forming a second metallic layer 45 on the P-GaN layer 43 and the transparent conductive electrode 46 by using the lithography process and the evaporating techniques for being filled in the via hole 46a to serve as a P-electrode of NiCr/Au, wherein the typical thickness of NiCr and Au are 50˜1000 Å and 200˜2000 Å respectively;

8. A step for forming a third metallic layer 44 on the N-contact area 47 by using the lithography process and the evaporating techniques for serving as a Ti/Pt/Au N-electrode, wherein the typical thickness of titanium (Ti), platinum (Pt), and gold (Au) are 50˜1000 Å, 50˜1000 Å, and 200˜2000 Å respectively; and

9. A step for forming a second bonding pad 48a containing a Ti/Au metallic layer on the second metallic layer 45 of the P-electrode and a third bonding pad 48b containing a Ti/Au metallic layer on the third metallic layer 44 of the N-electrode, wherein the typical thickness of titanium (Ti) is 50˜10000 Å while that of gold (Au) is 200˜20000 Å of both the second and the third bonding pads 48a, 48b.

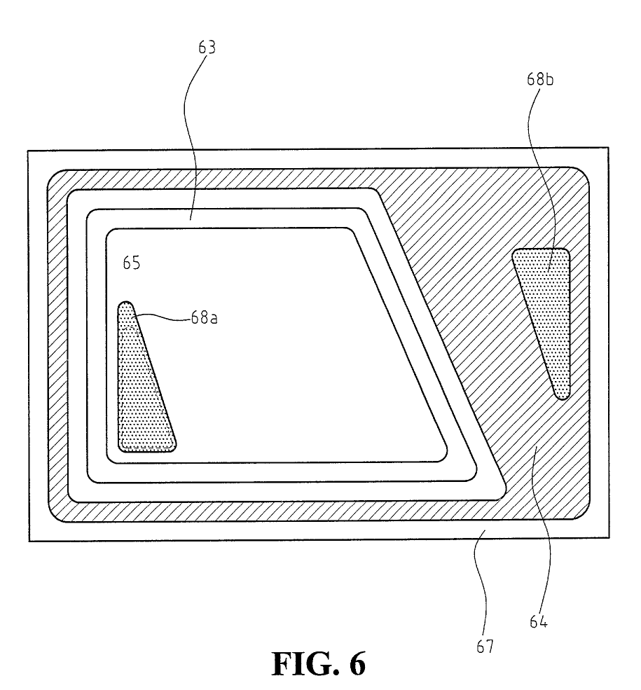

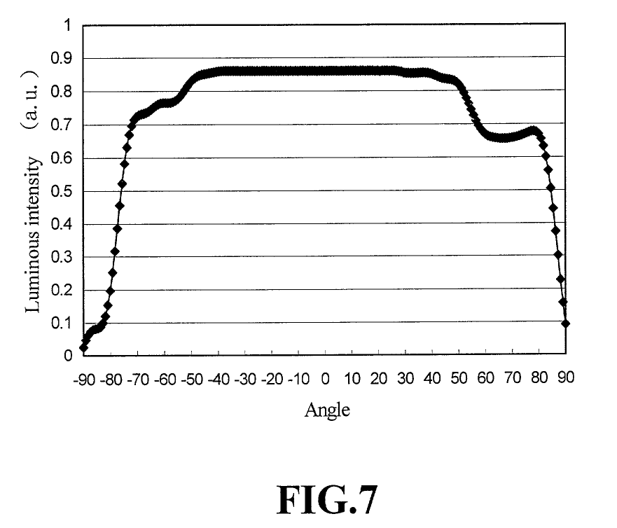

Now, according to a top view of an embodiment of GaN LED of this invention shown in FIG. 6, a far field beam pattern of the GaN LED made by the method of this invention shown in FIG. 7 is obviously improved in its central notch compared with the conventional one.

In the above described, at least one preferred embodiment has been described in detail with reference to the drawings annexed, and it is apparent that numerous variations or modifications may be made without departing from the true spirit and scope thereof, as set forth in the claims below.

What is claimed is:

1. A method for manufacturing GaN-based LED (Gallium-Nitride based Light-Emitting Diode), the procedure thereof comprising:
growing an N-GaN layer on a sapphire-wafer substrate;
growing a P-GaN layer on the N-GaN layer;
forming a trapezoid mask layer on the P-GaN layer;
etching to remove the part of P-GaN layer exposed so as to form an N-contact area, which passes through the P-GaN layer to reach the N-GaN layer;
removing the trapezoid mask layer;
forming a first metallic layer with a via hole on the P-GaN layer for serving as a transparent conductive electrode by using the lithography process and the evaporating techniques;
forming a second metallic layer on the first metallic layer and filled in the via hole for serving as a P-electrode;
forming a third metallic layer on the N-contact area by using the N-electrode; and
forming a second bonding pad on the second metallic layer of the P-electrode and a third bonding pad on the third metallic layer of the N-electrode.

2. The method according to claim 1, wherein the thickness of the N-GaN layer is 2˜3 μm approximately.

3. The method according to claim 1, wherein the thickness of the P-GaN layer is 0.1˜1 μm approximately.

4. The method according to claim 1, wherein the thickness of the mask layer is 200˜10000 Å made of nickel (Ni) or SiO₂ or any other suitable material.

5. The method according to claim 1, wherein the exposed part of the P-GaN layer under the trapezoid mask layer is etched to remove by a depth of 2000˜14000 Å by the ICP-RIE dry etching techniques.

6. The method according to claim 1, wherein the first metallic layer is a nickel/chromium (NiCr) film in thickness of 20˜300 Å.

7. The method according to claim 1, wherein the second metallic layer is substantially an NiCr/Au metallic layer, wherein a typical thickness of 50˜2000 Å is for NiCr and 200˜2000 Å for Au (gold) respectively.

8. The method according to claim 1, wherein the third metallic layer is substantially a Ti/Pt/Au layer, wherein a typical thickness of 50˜1000 Å is for titanium (Ti) and platinum (Pt), and 200˜2000 Å for gold (Au).

9. The method according to claim 1, wherein both the second and the third bonding layers are substantially Ti/Au metallic layers, wherein a typical thickness of 50˜10000 Å is for titanium and 200˜20000 Å for gold.

10. A method for manufacturing GaN-based LED (Gallium-Nitride based Light-Emitting Diode), the procedure thereof comprising:
growing an N-GaN layer on a sapphire-wafer substrate;
growing a P-GaN layer on the N-GaN layer;
forming a trapezoid mask layer on the P-GaN layer;
etching to remove the part of P-GaN layer exposed so as to form an N-contact area, which passes through the P-GaN layer to reach the N-GaN layer;
removing the trapezoid mask layer;
forming a first metallic layer with a via hole on the P-GaN layer for serving as a transparent conductive electrode by using the lithography process and the evaporating techniques;
forming a second metallic layer on the first metallic layer and filled in the via hole for serving as a P-electrode;
forming a third metallic layer on the N-contact area by using the lithography process and the evaporating techniques for serving as an N-electrode; and
forming a second or a third triangular bonding pad on the P-electrode or the N-electrode respectively by using the lithography process and the evaporating techniques, wherein those two triangular bonding pads are formed symmetrically to each other with respect to X and Y axes.

11. The method according to claim 10, wherein the thickness of the N-GaN layer is 2˜3 μm approximately.

12. The method according to claim 10, wherein the thickness of the P-GaN layer is 0.1˜1 μm approximately.

13. The method according to claim 10, wherein the thickness of the mask layer is 200˜10000 Å approximately made in nickel or SiO₂ or any other suitable material.

14. The method according to claim 10, wherein the exposed part of the P-GaN layer under the trapezoid mask layer is etched to remove by a depth of 2000˜14000 Å by the ICP-RIE dry etching techniques.

15. The method according to claim 1, wherein the first metallic layer is a nickel/chromium (NiCr) film in thickness of 20˜300 Å.

16. The method according to claim 1, wherein the second metallic layer is substantially an NiCr/Au metallic layer, wherein a typical thickness of 50˜2000 Å is for NiCr and 200˜2000 Å for Au (gold) respectively.

17. The method according to claim 1, wherein the third metallic layer is substantially a Ti/Pt/Au layer, wherein a typical thickness of 50˜1000 Å is for titanium (Ti) and platinum (Pt), and 200˜2000 Å for gold (Au).

18. The method according to claim 1, wherein both the second and the third bonding layers are substantially Ti/Au metallic layers, wherein a typical thickness of 50˜10000 Å is for titanium and 200˜20000 Å for gold.
